(19) United States
(12) Patent Application Publication
(10) Pub. No.: US 2017/0363966 A1
(43) Pub. Date: Dec. 21, 2017

(54) DISPLAY DEVICE

(71) Applicant: Japan Display Inc., Tokyo (JP)

(72) Inventors: Keita SASANUMA, Tokyo (JP); Hideki KURIYAMA, Tokyo (JP); Kohei HANASAKI, Tokyo (JP); Syou YANAGISAWA, Tokyo (JP); Kentaro AGATA, Tokyo (JP)

(21) Appl. No.: 15/616,130

(22) Filed: Jun. 7, 2017

(30) Foreign Application Priority Data
Jun. 17, 2016 (JP) 2016-120543

(51) Int. Cl. G03F 7/20; G03F 1/68

(52) U.S. Cl. CPC G03F 7/70258; G03F 7/70716; G03F 7/70691; G03F 1/68; G03F 7/70358; G03F 7/706

(57) ABSTRACT

The invention provides a display device that allows formation of the boundary of exposure at an arbitrary position on its substrate. A display device includes: a display area; a terminal; and a wire formed between the display area and the terminal and connected to the terminal. The wire includes a first part, a second part, and a third part. The first part extends in a first direction. The second part and the third part extend in a direction different from the first direction. The first part is located between the second and third parts and includes a protruding portion protruding in a second direction perpendicular to the first direction.

### CLAIM OF PRIORITY

The present application claims priority from Japanese Patent Application JP 2016-120543 filed on Jun. 17, 2016, the content of which is hereby incorporated by reference into this application.

### BACKGROUND OF THE INVENTION

### 1. Field of the Invention

The present invention relates to display devices and particularly to a display device capable of employing a high-density wiring and to a photomask for forming the high-density wiring.

### 2. Description of the Related Art

Since liquid crystal display devices and organic electroluminescent (EL) display devices can be made thin and light, they are used as various displays. Because fabricating such display devises individually is inefficient, many such devices are formed on a mother substrate. After the completion of the mother substrate, the display devices on the mother substrate are separated into individual units.

Large mother substrates have an advantage in terms of cost because many display devices can be fabricated at a time. To fabricate a display device, many photolithographic processes are performed, but the exposure device and photomasks used in the processes cannot easily be increased in size. Thus, exposure is performed on the entire surface of a large mother substrate by moving a small photomask. In other words, the same photomask is used repeatedly while the mother substrate is moved.

JP-A-2008-304716 discloses a mask pattern designing method that facilitates repetition of exposure. Specifically, a corrective wiring patterns are formed in the exposure frame (shot frame), or a blind frame is formed around the exposure frame with a space provided therebetween.

The boundary of the shot frame is prone to the problems of wire widening or narrowing due to exposure shortage or double exposure. JP-A-1999-135417 discloses a method for preventing wire widening or narrowing in which the shot frame does not take the form of a straight line but instead meanders, so that the position of the shot frame differs for each wire.

### SUMMARY OF THE INVENTION

The exposure device that performs exposure on a large mother substrate by using a small photomask while moving the mother substrate is also called the stepper, and the mask pattern within the exposure frame is used repeatedly. The exposure frame needs to be set accurately each time the boundary of the mask pattern is moved, that is, each time the mother substrate is moved. However, the limit of the setting accuracy of current steppers is approximately 1 μm.

To eliminate the irregularity of the amount of exposure at the shot boundary, a double exposure area having a predetermined width is formed. If a positive photoresist is used, the resist pattern is narrowed in this double exposure area. Conversely, if a negative photoresist is used, the resist pattern is widened in that area.

The screen resolution of liquid crystal display devices and an organic EL display devices is now getting higher. Accordingly, the width or pitch of wires is getting smaller. In such display devices, the irregularity of exposure at the mask frame may cause defects such as short circuits or disconnections of the wires. The problem becomes more serious at the oblique wiring portion where the wiring pitch is smaller.

An object of the invention is to prevent wire failures at the photomask boundary (shot boundary) in photolithography in which a stepper is used.

### Means for Solving the Problems

The invention is designed to achieve the above object and can be implemented as the following means.

(1) A display device includes: a display area; a terminal; and a wire formed between the display area and the terminal and connected to the terminal. In the display device, the wire includes a first part, a second part, and a third part, the first part extending in a first direction, the second and third parts extending in a direction different from the first direction, the first part being located between the second and third parts and including a protruding portion protruding in a second direction perpendicular to the first direction.

(2) A photomask including: first sides extending in a first direction; second sides parallel to the first sides; third sides each connecting one end of one of the first sides to one end of one of the second sides, the third sides extending in a second direction perpendicular to the first direction; fourth sides parallel to the third sides and each connecting the other end of one of the first sides to the other end of one of the second sides; and a plurality of wire patterns. In the photomask, the second and third sides meander across a first width in the first direction, each of the plurality of wire patterns includes a first part extending in the first direction and a second part slanted with respect to the second direction at a predetermined angle, and a protruding portion that protrudes in the second direction is formed on the first part at the position where the first part overlaps one of the second sides and one of the third sides.

### BRIEF DESCRIPTION OF THE DRAWINGS

FIG. 1 is a plan view illustrating part of a mother substrate being exposed to light with the use of a photomask;

FIG. 2 is a plan view of one of the many TFT substrates formed on the mother substrate of FIG. 1;

FIG. 3 is an enlarged plan view of the terminal area of FIG. 2 and its nearby area;

FIG. 4 is an enlarged plan view of the section of FIG. 3 that is enclosed by a one-dot chain line;

FIG. 5 is a plan view of the mask pattern used for the shot boundary of FIG. 4;

FIG. 6 is a plan view of the resist pattern (wiring pattern) resulting from exposure in which the photomask of FIG. 5 is used;

FIG. 7 is an enlarged plan view of the section of FIG. 3 that is enclosed by a one-dot chain line and that is based on the invention;

FIG. 8 is a plan view of the mask pattern of Embodiment 1 that is used for the shot boundary;

FIG. 9 is a plan view of the resist pattern (wiring pattern) resulting from exposure in which the photomask of FIG. 8 is used;

FIG. 10A is a plan view of a second photomask pattern;

FIG. 10B is a plan view of a first photomask pattern;

FIG. 10C is a plan view of the resist pattern (wiring pattern) resulting from exposure in which the photomasks of FIGS. 10A and 10B are used;

FIG. 11 is a plan view of the mask pattern of another example of Embodiment 2 that is used for the shot boundary;

FIG. 12 is a plan view of the resist pattern (wiring pattern) resulting from exposure in which the photomask of FIG. 11 is used;

FIG. 13 is a plan view of the mask pattern of still another example of Embodiment 2 that is used for the shot boundary;

FIG. 14 is a plan view of the resist pattern (wiring pattern) resulting from exposure in which the photomask of FIG. 13 is used;

FIG. 15 is a plan view of the mask pattern of yet another example of Embodiment 2 that is used for the shot boundary;

FIG. 16 is a plan view of the resist pattern (wiring pattern) resulting from exposure in which the photomask of FIG. 15 is used;

FIG. 17A is a plan view illustrating a case where the oblique wiring of FIG. 3 is formed on a single layer;

FIG. 17B is a cross section taken along line A-A of FIG. 17A;

FIG. 18A is a plan view illustrating a case where the oblique wiring of FIG. 3 is formed on two layers;

FIG. 18B is a cross section taken along line B-B of FIG. 18A;

FIG. 19A is a plan view illustrating another case where the oblique wiring of FIG. 3 is formed on two layers;

FIG. 19B is a cross section taken along line C-C of FIG. 19A;

FIG. 20A is a plan view of a second photomask pattern;

FIG. 20B is a plan view of a first photomask pattern; and

FIG. 20C is a plan view of the resist pattern (wiring pattern) resulting from exposure in which the photomasks of FIGS. 20A and 20B are used.

### DETAILED DESCRIPTION OF THE PREFERRED EMBODIMENTS

Embodiments of the present invention will now be described in detail. In the embodiments that follow, the direction parallel to the short sides of a TFT substrate 1 is assumed to be a first direction X while the direction parallel to the long sides of the TFT substrate 1 is assumed to be a second direction Y. The first direction X and the second direction Y are perpendicular to each other, but they can also cross each other at an angle other than 90 degrees.

### Embodiment 11

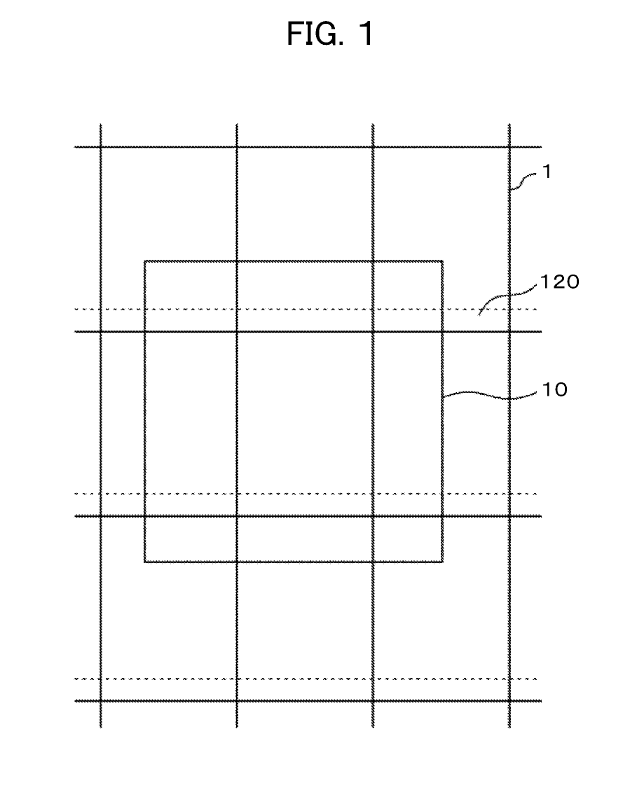

FIG. 1 is a plan view illustrating part of a mother substrate being exposed to light with the use of a photomask. The mother substrate includes thereon many TFT substrates 1 of liquid crystal display panels, but FIG. 1 illustrates only nine of them. On each of the TFT substrates 1, a thin film transistor (TFT), a pixel electrode, a common electrode, wiring, and so forth are formed. The lower part of each TFT substrate 1 is a terminal area 120 in which many terminals 130 are formed. The terminal area 120 also includes many wires that connect to the terminals 130. The TFT substrates 1 of FIG. 1 are used for liquid crystal display panels, but this is only meant to be an example. The invention can also be applied to substrates for other display panels including organic EL display panels.

In FIG. 1, the photomask 10 covers multiple TFT substrates 1 (hereinafter referred to also as substrates). If the size of the photomask 10 is a whole number multiple of the size of a substrate, exposure at the boundary of the photomask 10 can be made less irregular. However, there are many different sizes of display panels, and it is impossible to change the stepper or the size of the photomask based on the sizes of the display panels. Thus, the boundary of the photomask 10 needs to be set at an arbitrary position on the wiring pattern formed on the substrates 1.

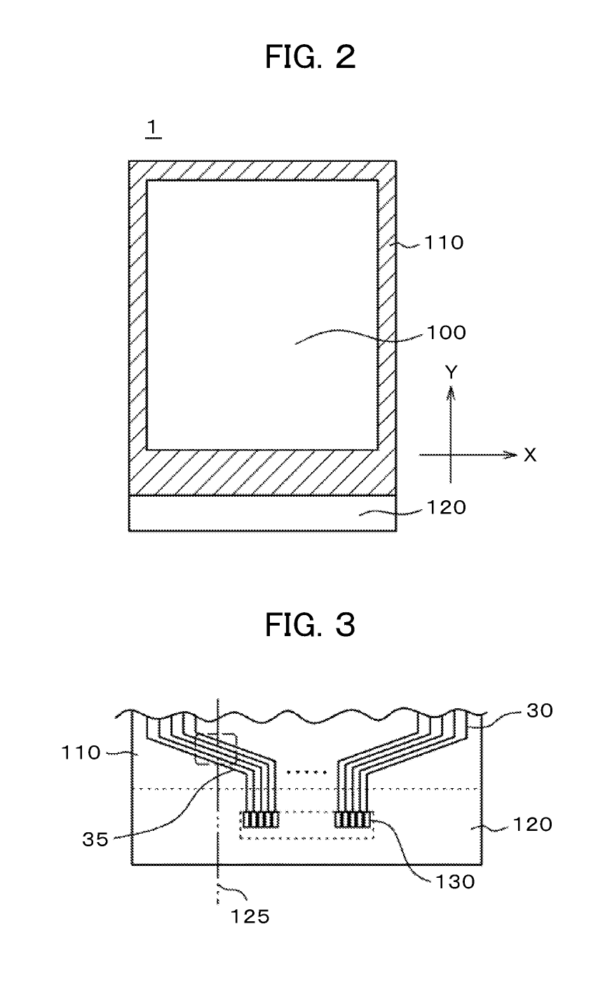

FIG. 2 is a plan view of one of the many TFT substrates formed on the mother substrate of FIG. 1. As illustrated in FIG. 2, a frame area 110 is formed around a display area 100. In the frame area 110 are many wires and the like. As further illustrated in FIG. 2, the terminal area 120 is formed outside the display area 100 and the frame area 110. Disposed in the terminal area 120 is a driver IC that drives the liquid crystal display panel. The driver IC is connected to at least part of the many wires via the terminals 130 formed on the frame area 110.

FIG. 3 is an enlarged plan view of the terminal area 120 of FIG. 2 and its nearby area. As illustrated in FIG. 3, in the frame area 110 adjacent to the terminal area 120, wires 30 have an oblique wiring portion 35, which is slanted with respect to the second direction Y. In the terminal area 120, the wires 30 run parallel to the second direction Y. This, however, is only meant to an example. In the actual product, the wires 30 can have an oblique wiring portion also in the terminal area 120.

In FIG. 3, the two-dot chain line 125 represents the exposure boundary (hereinafter referred to also as the shot boundary). This means that the exposure performed for the right side of the shot boundary 125 of FIG. 3 is different from that performed for the left side. Specifically, the exposure for the left side of the shot boundary 125 is performed with the use of a first photomask pattern while the exposure for the right side is performed with the use of a second photomask pattern.

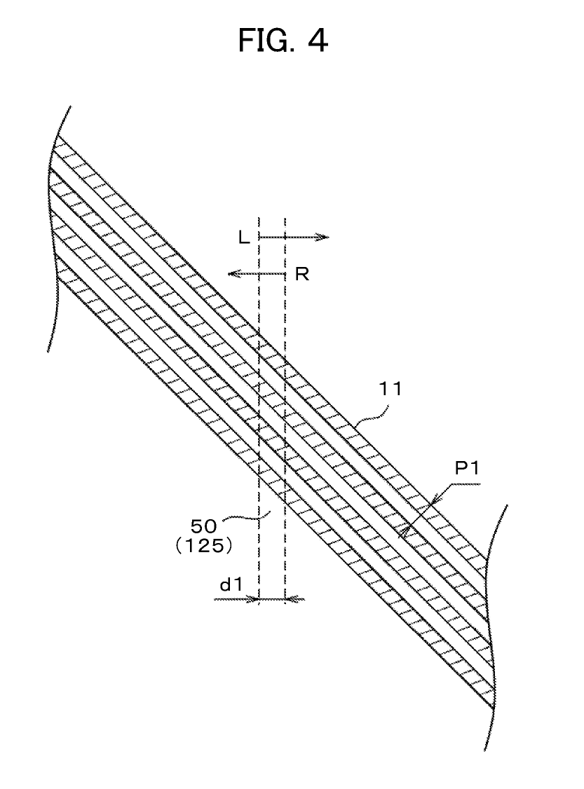

FIG. 4 is an enlarged plan view of the section of FIG. 3 that is enclosed by a one-dot chain line. At the oblique wiring portion 35, the pitch or width of the wires 30 is smaller than in other areas, which poses a problem. In FIG. 4, the arrow direction denoted by L indicates that the second photomask pattern is used for exposure while the arrow direction denoted by R indicates that the first photomask pattern is used for exposure.

As illustrated in FIG. 4, in order to prevent exposure shortage at the shot boundary 125, a double exposure area 50 having a predetermined width d1 is provided. That is, the double exposure area 50 is the place where overexposure occurs. In the case of a positive photoresist, the resist gets thinner where overexposure occurred, which may cause wire disconnections.

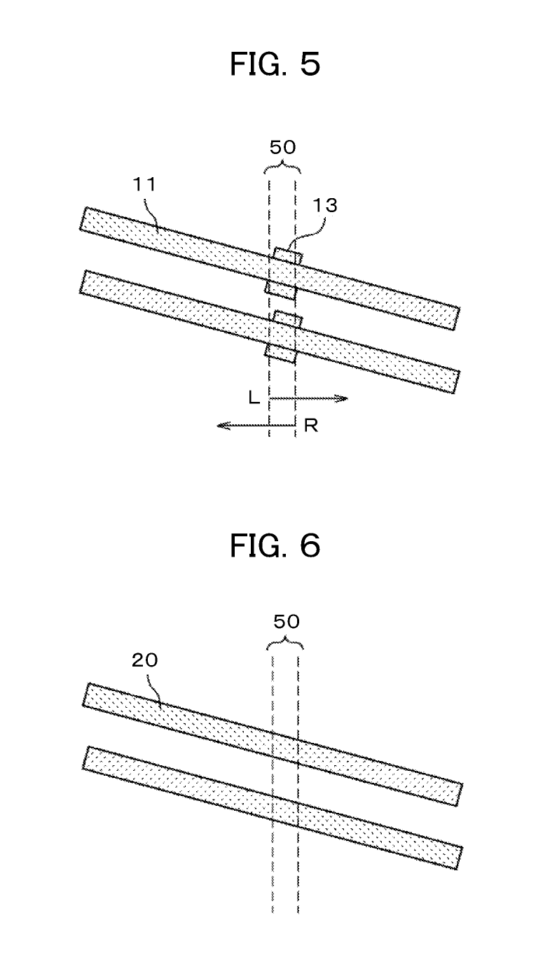

FIG. 5 is a plan view of pieces of the mask pattern 11 that are used for the shot boundary 125 of FIG. 4. In the double exposure area 50 of FIG. 5, a corrective pattern 13 is formed so that the width of the pieces of the mask pattern 11 will become larger at the corrective pattern 13 than in the other portions of the mask pattern 11. This corrective pattern 13 is used to compensate for the result of the overexposure due to the double exposure.

FIG. 6 illustrates the resist pattern 20 resulting from exposure in which the photomask of FIG. 5 is used. The resist pattern 20 is equivalent to a wiring pattern. The width of the wiring pattern pieces in the double exposure area 50 is kept the same as that in the other portions.

However, such divided exposure at the oblique wiring portion 35 as illustrated in FIG. 6 involves difficulties in forming the corrective pattern 13 because that is formed in an oblique direction, as is similar to the wiring forming direction. In other words, because a mask pattern is formed by combining grids, it requires time to form and adjust the corrective pattern 13, which is slight correction in an oblique direction. As a result, the number of steps required to draw the mask pattern will increase.

Also, since the wiring pitch is smaller at the oblique wiring portion 35, the formed pieces of the corrective pattern 13 are likely to be connected to each other, which may cause short circuits of the wires. Moreover, due to the small wiring pitch, the oblique wiring portion 35 is more subject to the influence of shot-to-shot variation of the exposure amount. As a result, the wiring pitch needs to be increased, and the wiring cannot be formed densely.

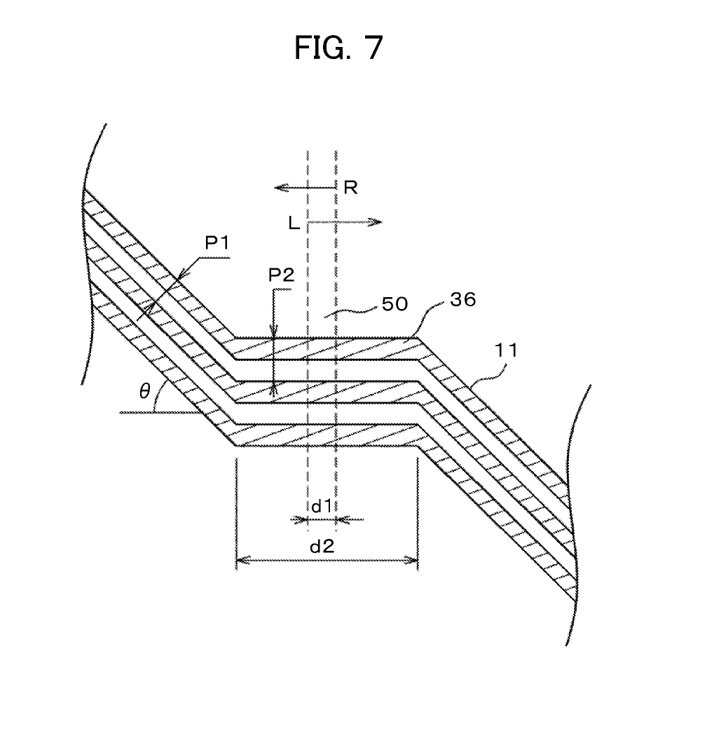

FIG. 7 is an enlarged plan view of the section of FIG. 3 that is enclosed by a one-dot chain line and that is based on the invention. As illustrated in FIG. 7, the oblique wiring portion 35 includes a horizontal wiring portion 36. The horizontal wiring portion 36 is parallel to the direction in which the photomask or the substrate moves relative to each other (hereinafter referred to also as the shot moving direction), that is, parallel to the first direction X. The length or width of the horizontal wiring portion 36 is represented by d2. The angle θ of the oblique wiring portion 35 in FIG. 7 is more than 0 degrees and less than 90 degrees. As illustrated in FIG. 7, the wiring pitch P2 of the horizontal wiring portion 36 can be made larger than the wiring pitch P1 at the oblique wiring portion 35. Thus, the width of each wire can also be made larger at the horizontal wiring portion 36. As a result, it is possible to reduce the influence of exposure amount variation at the shot boundary. In this embodiment, the corrective pattern 13 corresponds to protruding portions, the horizontal wiring portion 36 corresponding to a first part, the oblique wiring portion 35 connected to the horizontal wiring portion 36 corresponding to second and third parts.

In FIG. 7, the arrow direction denoted by L indicates a second photomask pattern is used for exposure while the arrow direction denoted by R indicates that a first photomask pattern is used for exposure. The width of the double exposure area 50 is d1. The width d1 of the double exposure area 50 in FIG. 7 is 2 μm or greater, which is larger than the minimum distance across which the stepper can move. The width d2 of the horizontal wiring portion 36 needs to be larger than the width d1 of the double exposure area 50 (i.e., d1<d2). The width d2 is preferably 3 μm or greater, more preferably 9 μm or greater. The upper limit of the width d2 of the horizontal wiring portion 36 is determined based on wiring layout conditions because too large a width d2 may affect the wiring layout.

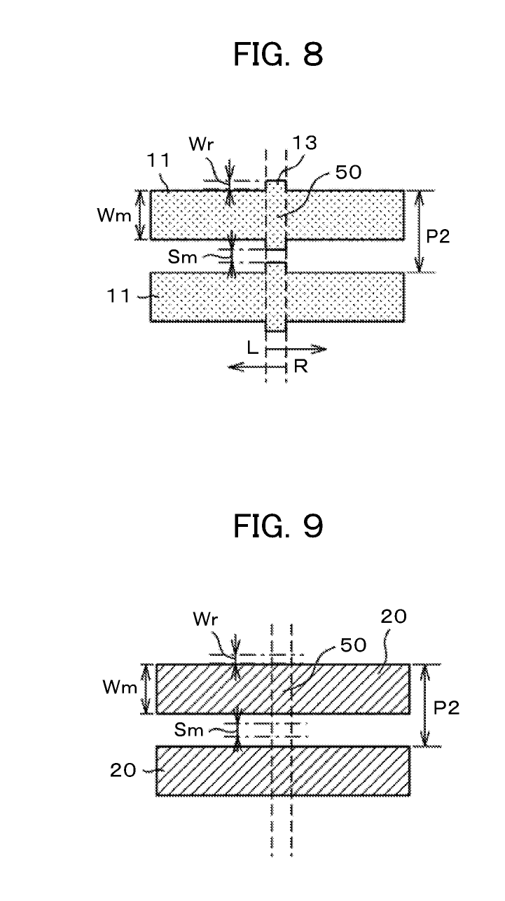

FIG. 8 is a plan view of the mask pattern of Embodiment 1 that is used for the shot boundary 125. In FIG. 8, the arrow direction denoted by L indicates a second photomask pattern is used for exposure while the arrow direction denoted by R indicates that a first photomask pattern is used for exposure. As illustrated, the corrective pattern 13 is formed in the double exposure area 50. The mask pattern pitch is P2, and the width of each piece of the mask pattern 11 is Wm. Also, the height of each piece of the corrective pattern 13 is Wr, and the minimum distance between the two pieces of the mask pattern 11 (in this case, the distance between adjacent two pieces of corrective pattern 13) is Sm. In this case, P2 is equal to Wm+2Wr+Sm. The height Wr of the pieces of the corrective pattern 13 is 0.5 μm or thereabout, and the minimum distance Sm between the two pieces of the mask pattern 11 is 3.0 μm or thereabout.

FIG. 9 is a plan view of the resist pattern 20 resulting from exposure in which the photomask of FIG. 8 is used. The resist pattern 20 is equivalent to a wiring pattern. Due to the presence of the corrective pattern 13, the width of the pieces of the wiring pattern in the double exposure area 50 is the same as that in the other portions. In other words, the width is the same in the double exposure area 50 and in the other portions of the wires. According to the invention, the wiring pattern width and wiring pitch at the double exposure area 50 can be kept the same as those in the other portions, as illustrated in FIG. 9. Therefore, wire short circuits and wire disconnections can be prevented.

### Embodiment 2

Embodiment 1 is an example in which the double exposure area 50 extends along a straight line. However, when the double exposure area 50 is disposed on a straight line, problems associated double exposure occur at the upper and lower portions of wires as viewed in plan view. As a result, wire short circuits and wire disconnections may be likely to occur.

Therefore, in Embodiment 2, the double exposure area 50 is caused to meander so that the position of the double exposure area 50 at the upper portion of a wire is different from that at the lower portion of the wire.

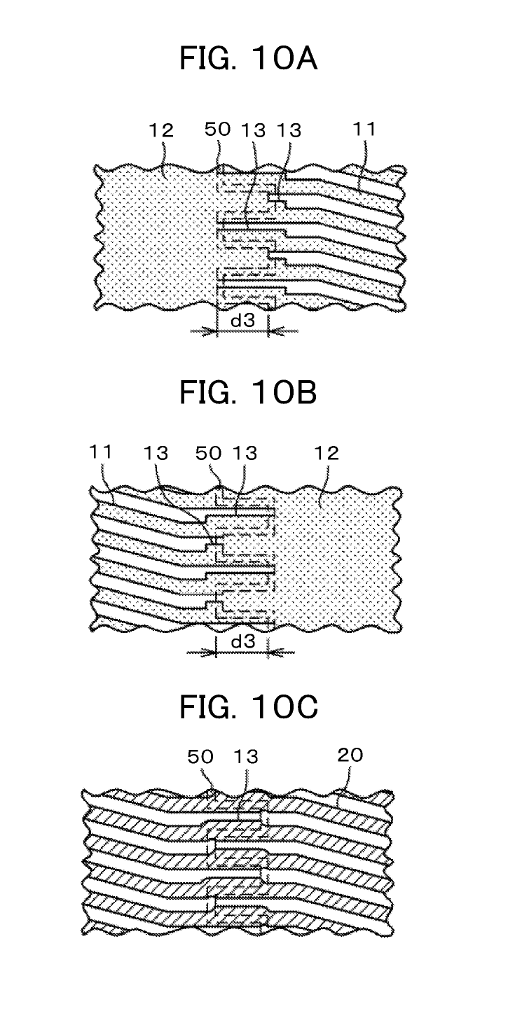

FIGS. 10A to 10C are plan views illustrating an exposure method according to Embodiment 2. FIG. 10A is a plan view illustrating a second photomask pattern. In FIG. 10A, the left side corresponds to a light blocking portion 12 while the right side corresponds to the mask pattern 11 used to form wiring by exposure. As illustrated in FIG. 10A, the double exposure area 50 meanders. In other words, the position where double exposure occurs differs between the upper and lower portions of a wire. The first part of the double exposure area 50 used for double exposure at the upper portion of a wire and the second part of the double exposure area 50 used for double exposure at the lower portion of the wire are displaced from each other by d3 in the shot moving direction, that is, the first direction X. In other words, d3 is the width across which the double exposure area 50 meanders. The meander width d3 of the double exposure area 50 is preferably larger than the width d1 of the double exposure area 50, for example, more than twice as large as the width d1. In addition, the width d3 of the double exposure area 50 is smaller than the width d2 of the horizontal wiring portion 36 of FIG. 6.

A corrective pattern 13 is formed between the first part and the second part, so as to prevent wire narrowing. This middle portion between the first part and the second part, that is, the portion parallel to the horizontal wiring portion 36, is also subjected to double exposure. This portion is formed so as to overlap a mask pattern 11, which corresponds to a wiring pattern, for the purpose of preventing diffraction of light.

FIG. 10B is a plan view illustrating a first photomask pattern. In FIG. 10B, the right side corresponds to the light blocking portion 12 while the left side corresponds to the mask pattern 11 used to form wiring by exposure. As illustrated in FIG. 10B, the double exposure area 50 meanders. That is, the first part of the double exposure area 50 used for double exposure at the upper portion of a wire and the second part of the double exposure area 50 used for double exposure at the lower portion of the wire are displaced from each other by d3 in the shot moving direction, that is, the first direction X.

Similar to FIG. 10A, a corrective pattern 13 is formed between the first part and the second part, so as to prevent wire narrowing. This middle portion between the first part and the second part, that is, the portion parallel to the horizontal wiring portion 36, is also subjected to double exposure. This portion is formed so as to overlap a mask pattern 11, which corresponds to a wiring pattern, for the purpose of preventing diffraction of light.

FIG. 10C illustrates the resist pattern 20 resulting from exposure in which the photomasks of FIGS. 10A and 10B are used. The resist pattern 20 is equivalent to a wiring pattern. As illustrated in FIG. 10C, the width of each piece of the wiring pattern at the first and second parts of the double exposure area 50 is kept similar to that in other portions where double exposure is not performed. On the other hand, the width of each piece of the wiring pattern is made larger on one side in the region where the double exposure area 50 runs parallel to the shot moving direction, or the first direction X.

The reason for the larger width is that by doing so, the middle portion of the double exposure area 50 between the first and second parts can be formed easily on a mask pattern 11, which corresponds to a wiring pattern, when the double exposure area 50 is caused to meander. The larger width is also for reducing the influence of light diffraction on patterning. In the present embodiment, the double exposure area 50 is formed so as to overlap the horizontal wiring portion 36, at which the wiring pitch is larger than that at the oblique wiring portion 35. Thus, the one-sided width increase of the middle portion does not have much influence.

On the side where the corrective pattern 13 is not formed, slight wire narrowing may occur. However, coupled with the wire width increase on the side where the corrective pattern 13 is formed, the width of each piece of the wiring pattern at the double exposure area 50 can at least be made equal to that at portions where double exposure is not performed. It should be noted that, in the present embodiment, slightly narrowed wire portions on the side where the corrective pattern 13 is not formed correspond to recessed portions.

FIG. 11 is a plan view of the mask pattern of another example of Embodiment 2 that is used for the shot boundary 125. In FIG. 11, the arrow direction denoted by L indicates a second photomask pattern is used for exposure while the arrow direction denoted by R indicates that a first photomask pattern is used for exposure. The mask pattern pitch is P2, and the width of each piece of the mask pattern 11 is Wm. Also, the height of each piece of the corrective pattern 13 is Wr, and the minimum distance between the two pieces of the mask pattern 11 (in this case, the distance between adjacent two pieces of corrective pattern 13) is Sm. In this case, P2 is equal to Wm+2Wr+Sm.

In FIG. 11, the corrective pattern 13 is formed corresponding to the double exposure area 50. Unlike FIGS. 10A to 10C, the width of the corrective pattern 13 in FIG. 11 is the same as that of the double exposure area 50. In other words, the width of the corrective pattern 13 in the first direction X is not made larger.

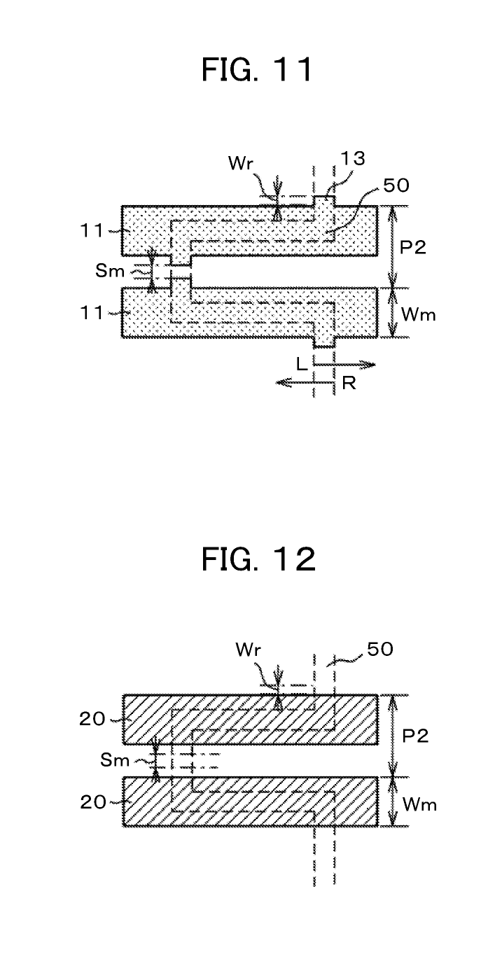

FIG. 12 is a plan view illustrating the resist pattern 20 resulting from exposure in which the photomask of FIG. 11 is used. The resist pattern 20 is equivalent to a wiring pattern. Due to the presence of the corrective pattern 13, the width of the pieces of the wiring pattern in the double exposure area 50 is the same as that in the other portions. As further illustrated in FIG. 12, FIG. 12 is different from FIG. 10C in that the width of the pieces of the wiring pattern stays the same across the regions where the double exposure area 50 extends in the first direction X. In this case, short circuits of the wires are less likely to occur although the influence of light diffraction in the double exposure area 50 is more likely to emerge depending on the accuracy of the stepper.

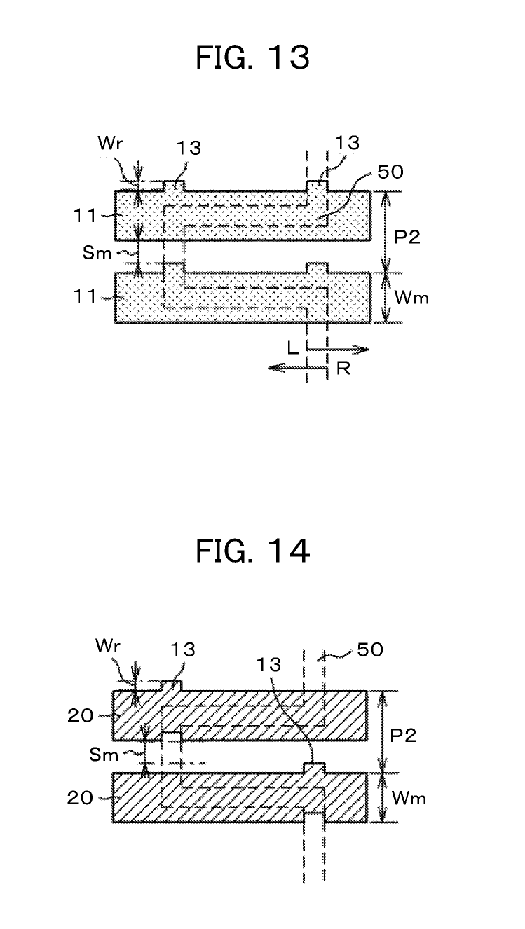

FIG. 13 is a plan view of the mask pattern of still another example of Embodiment 2 that is used for the shot boundary 125. The photomask layout and mask pattern pitch of FIG. 13 is the same as in FIG. 11. However, FIG. 13 differs from FIG. 11 in that, in the former, two pieces of the corrective pattern 13 are formed on one side of each piece of the mask pattern 11 at the interval equal to the meander width of the double exposure area 50. The width of the corrective pattern 13 of FIG. 13 is the same as that of the double exposure area 50.

FIG. 14 is a plan view illustrating the resist pattern 20 resulting from exposure in which the photomask of FIG. 13 is used. The resist pattern 20 is equivalent to a wiring pattern. In the double exposure area 50 of FIG. 14, wire narrowing will occur on the side where the corrective pattern 13 is not formed. However, due to the presence of the corrective pattern 13 on the other side, the width of each wire can at least be made equal to that of the pieces of the wiring pattern at portions where double exposure is not performed. Further in FIG. 14, because the width of the corrective pattern 13 is smaller than in FIGS. 10A to 10C, short circuit of the wires is less likely to occur.

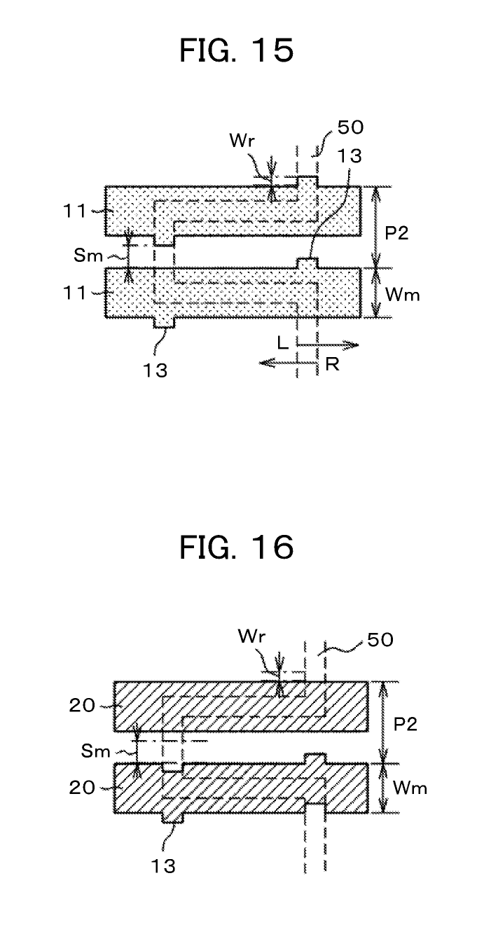

FIG. 15 is a plan view of the mask pattern of yet another example of Embodiment 2 that is used for the shot boundary 125. The photomask layout and mask pattern pitch of FIG. 15 is the same as in FIGS. 11 and 13. However, FIG. 15 differs from FIG. 13 in that, in FIG. 15, a piece of the mask pattern 11 has pieces of the corrective pattern 13 formed on its first and second parts (i.e., two pieces of the corrective pattern 13 are formed at portions overlapping the double exposure area 50) and a piece of the mask pattern 11 located below the former has pieces of the corrective pattern 13 formed on the opposite sides of its first and second parts. The width of the corrective pattern 13 of FIG. 15 is the same as that of the double exposure area 50.

FIG. 16 is a plan view illustrating the resist pattern 20 resulting from exposure in which the photomask of FIG. 15 is used. The resist pattern 20 is equivalent to a wiring pattern. In the double exposure area 50 of FIG. 16, wire narrowing will occur on the side where the corrective pattern 13 is not formed. However, due to the presence of the corrective pattern 13 on the other side, the width of each wire can at least be made equal to that of pieces of the wiring pattern at portions where double exposure is not performed. Further in FIG. 16, because the width of the corrective pattern 13 is smaller than in FIGS. 10A to 10C, short circuit of the wires is less likely to occur. Moreover, in FIG. 16, because the minimum distance Sm between two pieces of the mask pattern 11 is larger than in FIG. 11, short circuit of the wires is less likely to occur.

### Embodiment 3

In Embodiments 1 and 2, wires are formed on a single layer. However, the invention can also be applied to the case of multilayer wiring. In that case as well, such photomasks as mentioned in Embodiments 1 and 2 can be used to perform exposure on each layer.

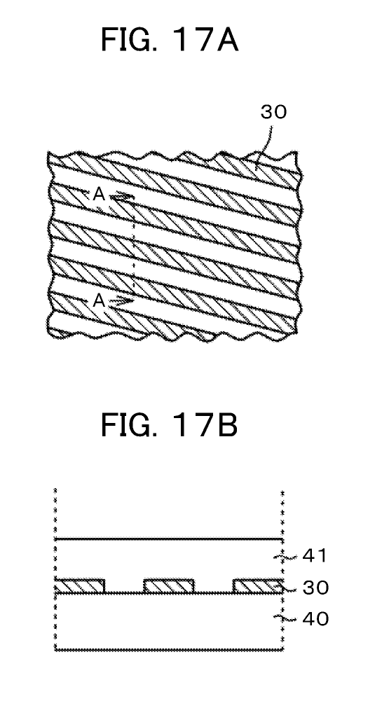

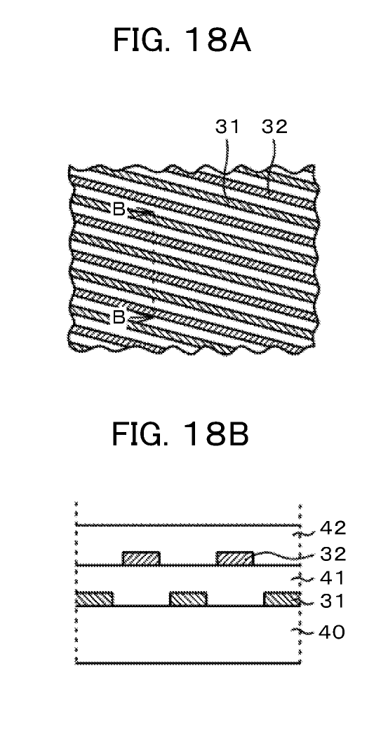

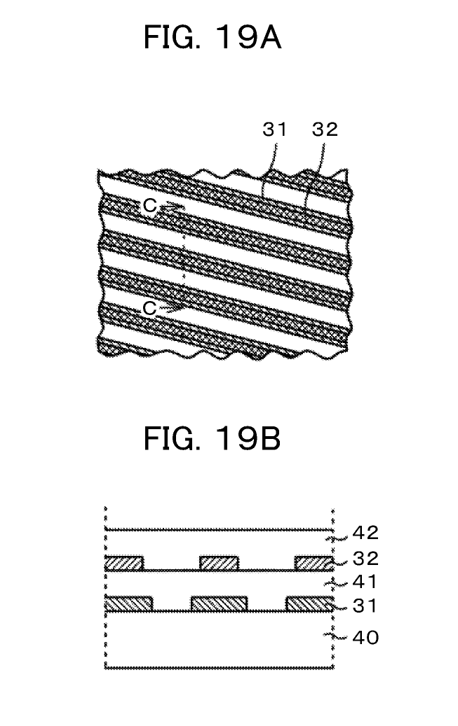

FIG. 17A is a plan view illustrating a case where the oblique wiring portion 35 of FIG. 3 is formed on a single layer while FIG. 17B is a cross section taken along line A-A of FIG. 17A. In FIG. 17B, the wires 30 are formed on a substrate 40, and a first insulating film 41 is formed to cover the wires 30 and the substrate 40. FIG. 18A is a plan view illustrating a case where the oblique wiring portion 35 of FIG. 3 is formed on two layers while FIG. 18B is a cross section taken along line B-B of FIG. 18A. In FIG. 18B, lower wires 31 are formed on the substrate 40, and the first insulating film 41 is formed to cover the lower wires 31 and the substrate 40. Further, upper wires 32 are formed on the first insulating film 41, and a second insulting film 42 is formed to cover the upper wires 32 and the first insulating film 41. In FIGS. 18A and 18B, the upper wires 32 are formed between the lower wires 31. FIG. 19A is a plan view illustrating another case where the oblique wiring portion 35 of FIG. 3 is formed on two layers while FIG. 19B is a cross section taken along line C-C of FIG. 19A. In FIG. 19B, the lower wires 31 are formed on the substrate 40, and the first insulating film 41 is formed to cover the lower wires 31 and the substrate 40. Further, the upper wires 32 are formed on the first insulating film 41, and the second insulting film 42 is formed to cover the upper wires 32 and the first insulating film 41. In FIGS. 19A and 19B, the upper wires 32 are formed so as to overlap the lower wires 31.

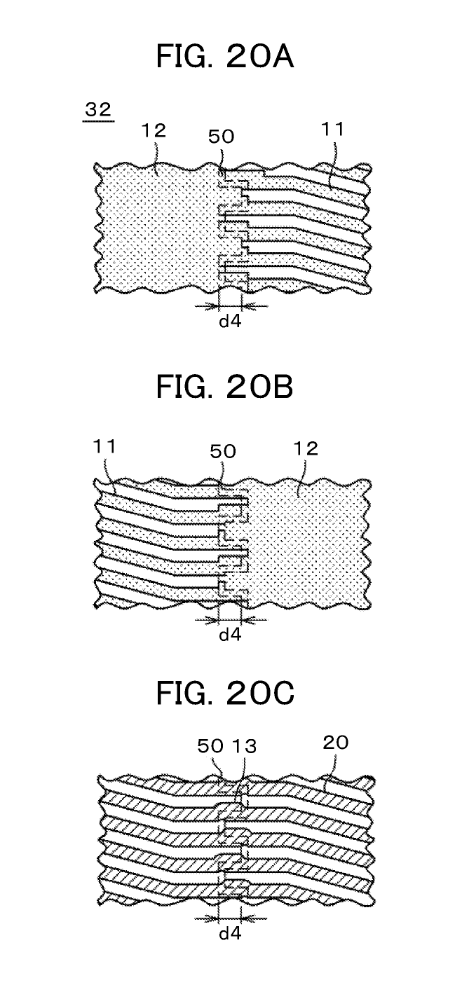

In the cases of FIGS. 18A through 19B, the exposure methods explained in Embodiments 1 and 2 can be used to form either of the upper wires 32 or the lower wires 31. Alternatively, as illustrated in FIGS. 20A to 20C, the mask pattern used for the shot boundary 125 can be changed in forming the lower wires 31 and the upper wires 32.

FIGS. 20A to 20C are plan views illustrating an exposure method for forming the lower wires 31. The upper wires 32 are formed by the same exposure method as that of FIGS. 10A to 10C. FIGS. 20A to 20C are the same as FIGS. 10A to 10C except that the meander width d4 of the double exposure area 50 of FIGS. 20A to 20C is smaller than the meander width d3 of the double exposure area 50 of FIGS. 10A to 10C.

In FIGS. 20A to 20C, the meander width of the double exposure area 50 for the lower wires 31 is larger than that for the upper wires 32. However, the invention can also be applied in the same manner to the opposite case where the meander width of the double exposure area 50 for the lower wires 31 is smaller than that for the upper wires 32. Further, if separate photomasks are to be used to form the lower wires 31 and the upper wires 32, the position of the shot boundary 125 can be changed. It should be noted that, in the present embodiment, the meander width d3 of the double exposure area 50 corresponds to a first width and that the meander width d4 of the double exposure area 50 corresponds to a second width.

In the above explanation, the shot moving direction is assumed to be a horizontal direction, that is, the first direction X. However, a similar explanation apples when the shot moving direction is the second direction Y. Also, although the photoresist is assumed to be of the positive type in the above explanation, a similar explanation applies when it is a negative photoresist. At portions where resist widening will occur in the case of the positive photoresist, resist narrowing will occur in the case of the negative photoresist. Conversely, at portions where resist narrowing will occur in the case of the positive photoresist, resist widening will occur in the case of the negative photoresist. Furthermore, the invention can be applied not only to liquid crystal display panels but also to organic EL display panels.

What is claimed is:

1. A display device comprising:
a display area;
a terminal; and
a wire formed between the display area and the terminal and connected to the terminal, wherein:
the wire includes a first part, a second part, and a third part;
the first part extends in a first direction;
the second and third parts extend in a direction different from the first direction; and
the first part is located between the second and third parts and includes a protruding portion protruding in a second direction perpendicular to the first direction.

2. The display device of claim 1, wherein the first part includes a recessed portion disposed on the side opposite the protruding portion.

3. The display device of claim 1, wherein the first part includes a recessed portion disposed on the side opposite the protruding portion and the recessed portion is formed at a position corresponding to the protruding portion in the second direction.

4. The display device of claim 2, wherein the length of the protruding portion in the first direction is larger than the length of the recessed portion in the first direction.

5. The display device of claim 1, wherein the second and third parts are slanted with respect to the second direction at a predetermined angle.

6. The display device of claim 1, wherein the first part includes a recessed portion disposed on the same side as the protruding portion.

7. The display device of claim 6, wherein the protruding portion and the recessed portion are spaced apart from each other in the second direction.
